(19) United States
(12) Patent Application Publication
(10) Pub. No.: US 2024/0087667 A1
(43) Pub. Date: Mar. 14, 2024

(54) Error Correction for Stacked Memory

(71) Applicant: Advanced Micro Devices, Inc., Santa Clara, CA (US)

(72) Inventors: Divya Madapusi Srinivas Prasad, Santa Clara, CA (US); Michael Ignatowski, Austin, TX (US); Gabriel Loh, Seattle, WA (US)

(73) Assignee: Advanced Micro Devices, Inc., Santa Clara, CA (US)

(21) Appl. No.: 18/458,052

(22) Filed: Aug. 29, 2023

Related U.S. Application Data
(60) Provisional application No. 63/404,828, filed on Sep. 8, 2022.

(51) Int. Cl. G11C 29/42

(52) U.S. Cl. CPC G11C 29/42

(57) ABSTRACT

Error correction for stacked memory is described. In accordance with the described techniques, a system includes a plurality of error correction code engines to detect vulnerabilities in a stacked memory and coordinate at least one vulnerability detected for a portion of the stacked memory to at least one other portion of the stacked memory.

### RELATED APPLICATION

This application claims priority under 35 U.S.C. § 119(e) to U.S. Provisional Patent Application No. 63/404,828, filed Sep. 8, 2022, and titled “Error Correction for Stacked Memory,” the entire disclosure of which is hereby incorporated by reference.

### BACKGROUND

Memory, such as random access memory (RAM), stores data that is used by the processor of a computing device. Due to advancements in memory technology, various types of memories, including various non-volatile and volatile memories, are being deployed for numerous applications. Examples of such non-volatile memories include, for instance, Ferro-electric memory and Magneto-resistive RAM, and examples of such volatile memories include static random-access memory (SRAM) and dynamic random-access memory (DRAM), including high bandwidth memory and other stacked variants of DRAM. However, conventional configurations of these memories have limitations, which can restrict their use in connection with some deployments.

### BRIEF DESCRIPTION OF THE DRAWINGS

FIG. 1 is a block diagram of a non-limiting example system having a memory and a controller operable to implement error correction for stacked memory.

FIG. 2 depicts a non-limiting example of a printed circuit board architecture for high bandwidth memory.

FIG. 3 depicts a non-limiting example of a stacked memory architecture.

FIG. 4 depicts a non-limiting example of error correction code memory without coordinated error correction.

FIG. 5 depicts a non-limiting example of coordinated error correction between tiers of memory.

FIG. 6 depicts another non-limiting example of coordinated error correction between tiers of memory.

FIG. 7 depicts a non-limiting example of another stacked memory architecture.

FIG. 8 depicts a non-limiting example of a non-stacked memory architecture having a memory and processor on a single die.

FIG. 9 depicts a procedure in an example implementation of error correction for stacked memory.

### DETAILED DESCRIPTION

Overview

The memory wall has been referred to as one of the key limiters in pushing the bounds of computation in modern systems. High bandwidth memory (HBM) and other stacked dynamic random-access memory (DRAM) memories are increasingly utilized to alleviate off-chip memory access latency and bandwidth as well as to increase memory density. Despite these advances, conventional systems treat multi-tiered memories as stacked “2D” memory macros. Doing so results in fundamental limitations in how much bandwidth and speed stacked “3D” memories can achieve.

To overcome these problems, error correction for stacked memory is described. The described techniques coordinate error correction code (ECC) mechanisms between tiers (e.g., dies) of memory, improving performance, power efficiency, and RAS (i.e., reliability, availability, and serviceability) of stacked memories relative to conventional ECC approaches which do not coordinate ECC between the different tiers. This coordination between tiers is referred to as “coordinated 3D ECC”. The described techniques provide advantages over conventional ECC memory, which has significant overhead in terms of power (e.g., ECC occurs with every memory read) and performance. This is, at least in part, because conventional systems leverage a 2D ECC approach for each tier of memory and thus incur the performance and power overhead for each die. In some cases, correctable errors in memory are be missed using conventional techniques.

In some aspects, the techniques described herein relate to a system including: a stacked memory, and a plurality of error correction code engines to detect vulnerabilities in the stacked memory and coordinate at least one vulnerability detected for a portion of the stacked memory to at least one other portion of the stacked memory.

In some aspects, the techniques described herein relate to a system, wherein the portion of the stacked memory and the at least one other portion of the stacked memory correspond to different memory dies.

In some aspects, the techniques described herein relate to a system, wherein the stacked memory is a DRAM memory.

In some aspects, the techniques described herein relate to a system, wherein coordination of the at least one vulnerability includes exchanging a vulnerability correlation map between at least two error correction code engines.

In some aspects, the techniques described herein relate to a system, wherein error correction code engines disposed on different tiers of the stacked memory are communicably coupled.

In some aspects, the techniques described herein relate to a system, wherein the coordination of the at least one vulnerability includes a first error correction code engine communicating with a second error correction code engine.

In some aspects, the techniques described herein relate to a system, wherein at least one engine of the plurality of error correction code engines is disposed between tiers of the stacked memory.

In some aspects, the techniques described herein relate to a method including: detecting, by an error correction code engine of a plurality of error correction code engines within a stacked memory, a vulnerability in a portion of the stacked memory, and coordinating the vulnerability with at least one other portion of the stacked memory based on the error correction code engine exchanging information about the vulnerability with at least one other error correction code engine of the plurality of error correction code engines.

In some aspects, the techniques described herein relate to a method, wherein the error correction code engine is communicatively coupled to the at least one other error correction code engine.

In some aspects, the techniques described herein relate to a method, wherein the coordinating further includes communicating, by the error correction code engine, the information about the vulnerability to the at least one other error correction code engine.

In some aspects, the techniques described herein relate to a method, wherein the information includes a vulnerability correlation map.

In some aspects, the techniques described herein relate to a method, wherein the portion of the stacked memory and the at least one other portion of the stacked memory correspond to different memory dies.

In some aspects, the techniques described herein relate to a method, wherein the stacked memory is a DRAM memory.

In some aspects, the techniques described herein relate to a method, wherein coordination of the at least one vulnerability includes exchanging a vulnerability correlation map between at least two error correction code engines.

In some aspects, the techniques described herein relate to a system including: a stacked memory including a plurality of dies, a first error correction code engine associated with a first die of the plurality of dies, and a second error correction code engine associated with a second die of the plurality of dies, wherein the first error correction code engine and the second error correction code engine are configured to coordinate at least one vulnerability detected for at least one of the first die or the second die of the plurality of dies.

In some aspects, the techniques described herein relate to a system, wherein the first error correction code engine is configured to detect a vulnerability associated with the first die of the plurality of dies.

In some aspects, the techniques described herein relate to a system, wherein the first error correction code engine is further configured to communicate information about the vulnerability to the second error correction code engine.

In some aspects, the techniques described herein relate to a system, wherein the second error correction code engine is configured to detect a vulnerability associated with the second die of the plurality of dies and communicate information about the vulnerability to the first error correction code engine.

In some aspects, the techniques described herein relate to a system, wherein the stacked memory is a DRAM memory.

In some aspects, the techniques described herein relate to a system, wherein the first error correction code engine and the second error correction code engine are configured to coordinate at least one vulnerability by exchanging a vulnerability correlation map.

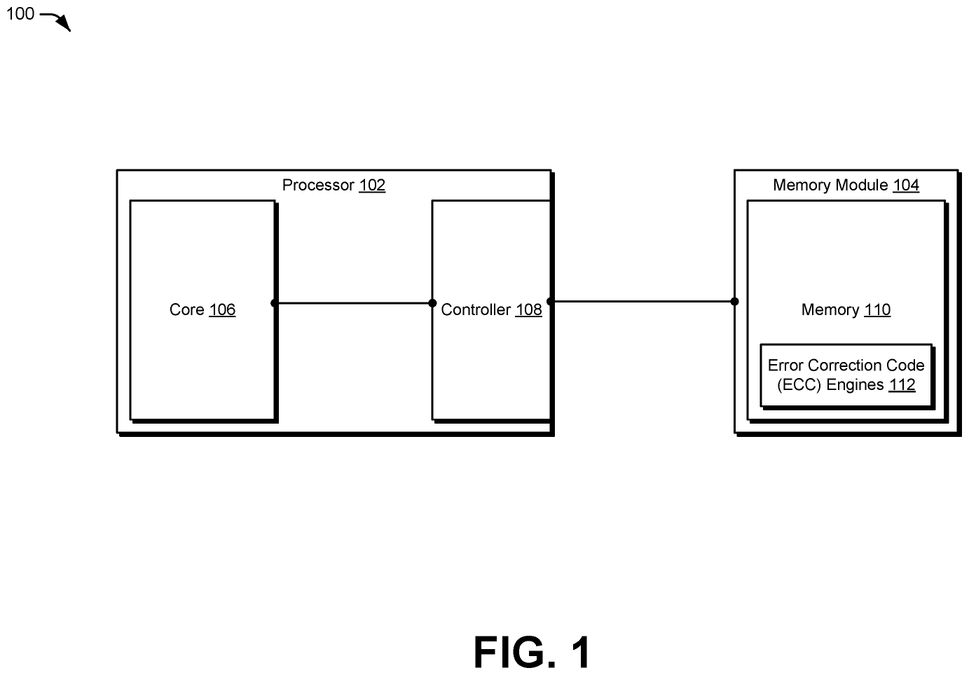

FIG. 1 is a block diagram of a non-limiting example system 100 having a memory and a controller operable to implement error correction for stacked memory. In this example, the system 100 includes processor 102 and memory module 104. Further, the processor 102 includes a core 106 and a controller 108. The memory module 104 includes memory 110. In accordance with the described techniques, the memory 110 includes error correction code engines 112, also referred to herein as ECC engines 112. In variations, the memory 110 includes multiple ECC engines, as discussed in more detail below, such as an ECC engine per tier (e.g., die) in a stacked configuration of the memory 110. In one or more implementations, the memory module 104 includes a processing-in-memory component (not shown).

In accordance with the described techniques, the processor 102 and the memory module 104 are coupled to one another via a wired or wireless connection. The core 106 and the controller 108 are also coupled to one another via one or more wired or wireless connections. Example wired connections include, but are not limited to, buses (e.g., a data bus), interconnects, through silicon vias, traces, and planes. Examples of devices in which the system 100 is implemented include, but are not limited to, servers, personal computers, laptops, desktops, game consoles, set top boxes, tablets, smartphones, mobile devices, virtual and/or augmented reality devices, wearables, medical devices, systems on chips, and other computing devices or systems.

The processor 102 is an electronic circuit that performs various operations on and/or using data in the memory 110. Examples of the processor 102 include, but are not limited to, a central processing unit (CPU), a graphics processing unit (GPU), an accelerator, a field programmable gate array (FPGA), an accelerated processing unit (APU), a neural processing unit (NPU), a tensor processing unit (TPU), an artificial intelligence engine (AIE), and a digital signal processor (DSP). The core 106 is a processing unit that reads and executes instructions (e.g., of a program), examples of which include to add, to move data, and to branch. Although one core 106 is depicted in the illustrated example, in variations, the processor 102 includes more than one core 106, e.g., the processor 102 is a multi-core processor. In implementations where the system 100 includes more than one core, in at least one variation, those cores include more than one type of core, such as CPUs, GPUs, FPGAs, and so forth.

In one or more implementations, the memory module 104 is a circuit board (e.g., a printed circuit board), on which the memory 110 is mounted. In variations, one or more integrated circuits of the memory 110 are mounted on the circuit board of the memory module 104. Examples of the memory module 104 include, but are not limited to, a TransFlash memory module, single in-line memory module (SIMM), and dual in-line memory module (DIMM). In one or more implementations, the memory module 104 is a single integrated circuit device that incorporates the memory 110 on a single chip or die. In one or more implementations, the memory module 104 is composed of multiple chips or dies that implement the memory 110 that are vertically (“3D”) stacked together, are placed side-by-side on an interposer or substrate, or are assembled via a combination of vertical stacking or side-by-side placement.

The memory 110 is a device or system that is used to store information, such as for immediate use in a device, e.g., by the core 106 of the processor 102 and/or by a processing-in-memory component. In one or more implementations, the memory 110 corresponds to semiconductor memory where data is stored within memory cells on one or more integrated circuits. In at least one example, the memory 110 corresponds to or includes volatile memory, examples of which include random-access memory (RAM), dynamic random-access memory (DRAM), synchronous dynamic random-access memory (SDRAM), and static random-access memory (SRAM). Alternatively or in addition, the memory 110 corresponds to or includes non-volatile memory, examples of which include Ferro-electric RAM, Magneto-resistive RAM, flash memory, read-only memory (ROM), programmable read-only memory (PROM), erasable programmable read-only memory (EPROM), and electronically erasable programmable read-only memory (EEPROM).

In one or more implementations, the memory 110 is configured as a dual in-line memory module (DIMM). A DIMM includes a series of dynamic random-access memory integrated circuits, and the modules are mounted on a printed circuit board. Examples of types of DIMMs include, but are not limited to, synchronous dynamic random-access memory (SDRAM), double data rate (DDR) SDRAM, double data rate 2 (DDR2) SDRAM, double data rate 3 (DDR3) SDRAM, double data rate 4 (DDR4) SDRAM, and double data rate 5 (DDR5) SDRAM. In at least one variation, the memory 110 is configured as a small outline DIMM (SO-DIMM) according to one of the above-mentioned SDRAM standards, e.g., DDR, DDR2, DDR3, DDR4, and DDR5. It is to be appreciated that the memory 110 is configurable in a variety of ways without departing from the spirit or scope of the described techniques.

In conventional approaches, stacked memories (e.g., DRAM) are refreshed at a “static” or “fixed” rate, e.g., per Joint Electron Device Engineering Council (JEDEC) specification. Due to this, conventional approaches refresh all memories at a refresh rate which corresponds to a “worst case” or “pessimistic case” refresh time, such as around 64 milliseconds. However, this can limit performance (e.g., instructions per cycle) and, due to “unnecessary” refreshes, the power overhead of using a static refresh rate is higher than for the described techniques.

By way of example, various conventional DDR5 configurations of DRAM have Performance-Power-Area (PPA) limitations when accessing data off-chip. A typical DRAM bit cell consists of a one transistor-one capacitor (1T-1C) structure, where a capacitor is formed by a dielectric layer sandwiched between conductor plates. The performance of conventional systems is limited by DRAM bandwidth and latency, such as with memory-heavy workloads. By way of contrast, the system 100 is capable of taking advantage of the stacked architecture of 3D memories (e.g., DRAM) by coordinating error correction code (ECC) mechanisms between multiple (e.g., at least two) tiers (e.g., die) of a stacked memory according to one or more algorithms, so that use of at least one ECC mechanism may be reduced or eliminated for an ECC event.

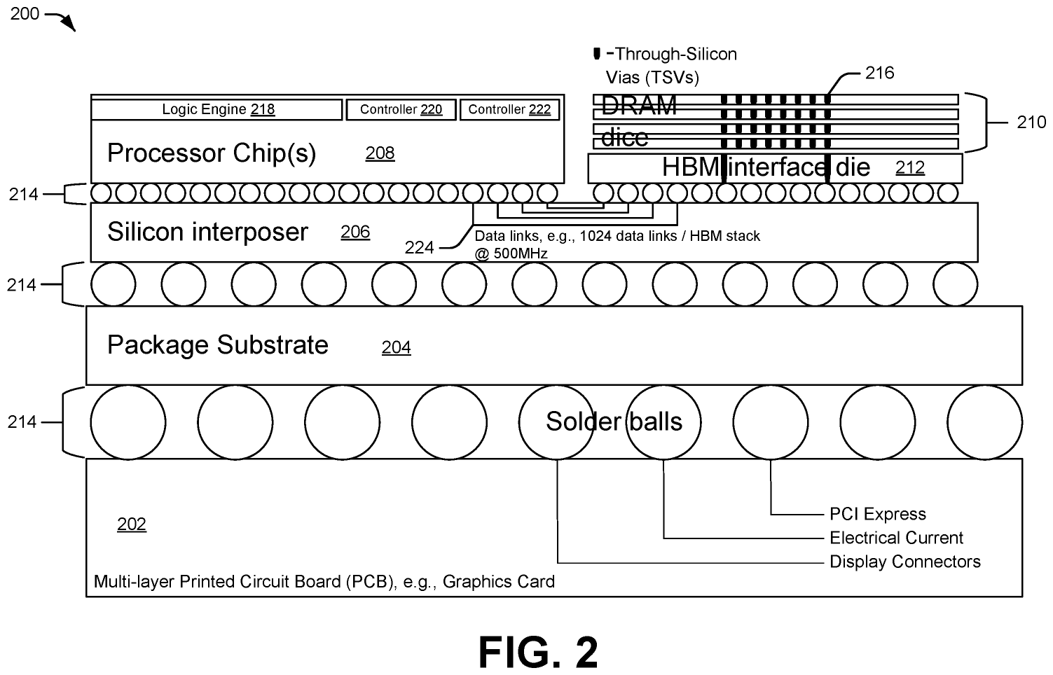

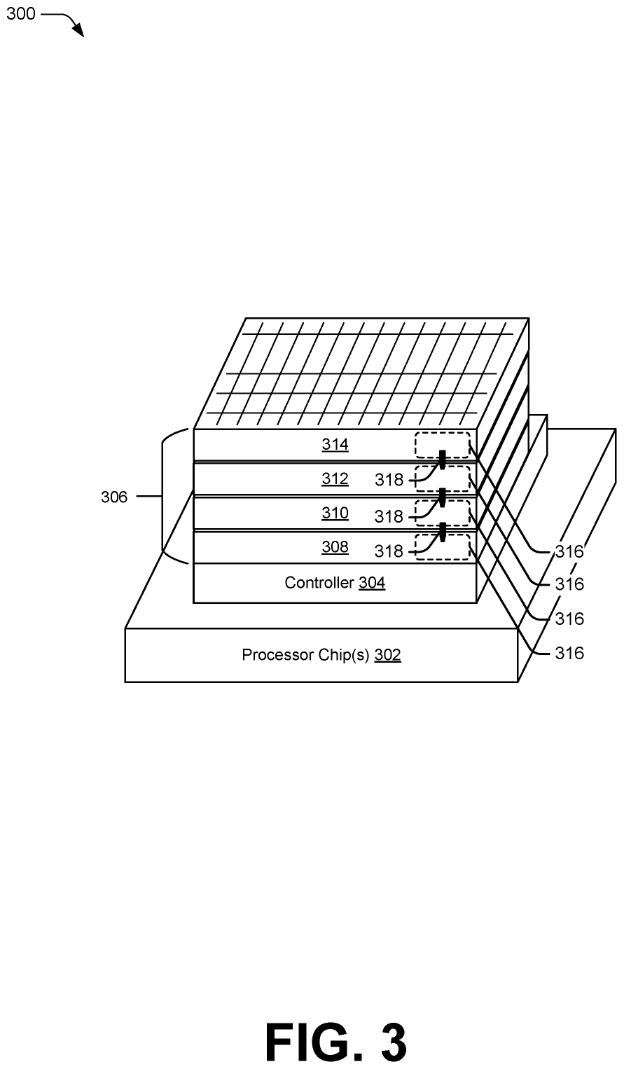

High bandwidth memory (HBM) provides increased bandwidth and memory density, allowing multiple layers (e.g., tiers) of DRAM dies (e.g., 8-12 dies) to be stacked on top of one another with one or more optional logic/memory interface die. Such a memory stack can be connected to a processing unit (e.g., CPU and/or GPU) through silicon interposers, as discussed in more detail below in relation to FIG. 2. Alternatively or additionally, such a memory stack can be stacked on top of a processing unit (e.g., CPU and/or GPU), as discussed in more detail below in relation to FIG. 3. In one or more implementations, stacking the memory stack on top of a processing unit can provide further connectivity and performance advantages relative to connections through silicon interposers.

The controller 108 is a digital circuit that manages the flow of data to and from the memory 110. By way of example, the controller 108 includes logic to read and write to the memory 110 and interface with the core 106, and in variations a processing-in-memory component. For instance, the controller 108 receives instructions from the core 106 which involve accessing the memory 110 and provides data to the core 106, e.g., for processing by the core 106. In one or more implementations, the controller 108 is communicatively located between the core 106 and the memory module 104, and the controller 108 interfaces with both the core 106 and the memory module 104.

In accordance with the described techniques, the memory 110 includes ECC engines 112, such as at least one ECC engine per tier (e.g., die) of the memory 110 (e.g., when the memory has a stacked memory configuration). In one or more implementations, an ECC engine is a hardware and/or software component that implements one or more error correction code algorithms. In at least one hardware implementation, for instance, at least one of the ECC engines 112 is a controller that is integral with and/or embedded in the memory 110 to identify and/or correct errors present in the data stored in the memory 110, e.g., according to one or more such error correction code algorithms. In one or more implementations, an ECC engine 112 is a dedicated circuit, such as a block of semiconducting material (or a portion of a die) on which the given functional circuit is fabricated. For example, the functional circuit of an ECC engine is deposited on such semiconducting material using a process, such as photolithography. Where the ECC engines 112 are integral with a portion of the memory 110, for instance, the memory 110 includes one or more ECC engines fabricated on or soldered to dies of the memory 110. Alternatively or additionally, an ECC engine is implemented in software, such that one or more portions of the memory 110 (e.g., at least a portion of each die of the memory) is reserved for running program code that implements the ECC engine. Example sources of errors in the data in the memory 110 include, for instance, hardware failures, signal noise, and interference, to name just a few. Alternatively or additionally, at least one of the ECC engines 112 is implemented in software. For instance, an ECC engine is a program loaded into the memory 110 (or a portion of the memory 110) to identify and/or correct errors present in the data stored in the memory 110 according to the one or more error correction code algorithms. The ECC engines 112 improve the reliability and robustness of a device that includes the system 100 by correcting errors on the fly and maintaining system operation even in the presence of errors.

In one or more implementations, the ECC engines 112 use extra bits (i.e., redundancy) added to the data being stored in the memory to identify and correct errors that occur, such as due to one or more of the hardware failures, signal noise, interference, and so on, mentioned above. In one or more implementations, the ECC engines 112 or some other component(s) (e.g., the memory 110) add redundancy to the information being stored using an algorithm. For example, the ECC engines 112 or other component(s) add a redundant bit that is a function of one or more original information bits, e.g., the data being stored. Codes that include the unmodified original information input to the algorithm are referred to as “systematic” codes, whereas codes that do not include the unmodified original information input to the algorithm are referred to as “non-systematic” codes. Categories of error correction codes include, for example, block codes which work on fixed-sized blocks of bits of data of a predetermined size and convolutional codes that work on bits or symbols of arbitrary length. It is to be appreciated that in variations, the particular ECC implemented by the ECC engines 112 differ without departing from the spirit or scope of the described techniques.

In contrast to conventional techniques, the described techniques identify and detect errors in the memory 110 by using at least two of the ECC engines 112 per error correction operation and/or per detectable event. In other words, at least two of the ECC engines 112 coordinate to perform ECC for the memory 110 by communicating with one another (e.g., unidirectionally, bi-directionally, and/or multi-directionally). In accordance with the described techniques, for instance, an ECC engine communicates with at least one other ECC engine of the ECC engines 112 to identify and/or correct the errors in the memory 110, thereby leveraging the information of different ECC engines (e.g., on different tiers of the memory 110) and thus treating the memory 110 as a true 3D structure. In one or more implementations, ECC engines perform correlation of exchanged information, while in other implementations the ECC engines performing one or more non-correlating actions and/or corrections.

FIG. 2 depicts a non-limiting example 200 of a printed circuit board architecture for high bandwidth memory.

The illustrated example 200 includes a printed circuit board 202, which is depicted as a multi-layer printed circuit board in this case. In one example, the printed circuit board 202 is used to implement a graphics card. It should be appreciated that the printed circuit board 202 can be used to implement other computing systems without departing from the spirit or scope of the described techniques, such as a central processing unit (CPU), a graphics processing unit (GPU), a field programmable gate array (FPGA), an accelerated processing unit (APU), and a digital signal processor (DSP), to name just a few.

In the illustrated example 200, the layers of the printed circuit board 202 also include a package substrate 204, a silicon interposer 206, processor chip(s) 208, memory dies 210 (e.g., DRAM dies), and a interface die 212 (e.g., a high bandwidth memory (HBM) controller die). The illustrated example 200 also depicts a plurality of solder balls 214 between various layers. Here, the example 200 depicts the printed circuit board 202 as a first layer and the package substrate 204 as a second layer with a first plurality of solder balls 214 disposed between the printed circuit board 202 and the package substrate 204. In one or more implementations, this arrangement is formed by depositing the first plurality of the solder balls 214 between the printed circuit board 202 and the package substrate 204. Further, the example 200 depicts the silicon interposer 206 as a third layer, with a second plurality of the solder balls 214 deposited between the package substrate 204 and the silicon interposer 206. In this example 200, the processor chip(s) 208 and the interface die 212 are depicted on a fourth layer, such that a third plurality of the solder balls 214 are deposited between the silicon interposer 206 and the processor chip(s) 208 and a fourth plurality of the solder balls 214 are deposited between the silicon interposer 206 and the interface die 212. In this example, the memory dies 210 form an additional layer (e.g., a fifth layer) arranged “on top” of the interface die 212. The illustrated example 200 also depicts through silicon vias 216 in each die of the memory dies 210 and in the interface die 212, such as to connect these various components. It should be appreciated that the plurality of solder balls 214 can be implemented by other electric couplings without departing from the spirit or scope of the described techniques, such as microbumps, copper pillars, copper micropillars, and so forth.

It is to be appreciated that systems for error correction for stacked memory may be implemented using different architectures in one or more variations without departing from the spirit or scope of the described techniques. For example, any of the above-discussed components (e.g., the printed circuit board 202, the package substrate 204, the silicon interposer 206, the processor chip(s) 208, the memory dies 210 (e.g., DRAM dies), and the interface die 212 (e.g., a high bandwidth memory (HBM) controller die) may be arranged in different positions in a stack, side-by-side, or a combination thereof in accordance with the described techniques. Alternatively or in addition, those components may be configured differently than depicted, e.g., the memory dies 210 may include only a single die in one or more variations, the architecture may include one or more processor chips 208, and so forth. In at least one variation, one or more of the described components is not included in an architecture for implementing error correction for stacked memory in accordance with the described techniques.

In this example 200, the processor chip(s) 208 is depicted including logic engine 218, a first controller 220, and a second controller 222, which is optional. In variations, the processor chip(s) 208 includes more, different, or fewer components without departing from the spirit or scope of the described techniques. In one or more implementations, such as graphics card implementations, the logic engine 218 is configured as a three-dimensional (3D) engine. Alternatively or in addition, the logic engine 218 is configured to perform different logical operations, e.g., digital signal processing, machine learning-based operations, and so forth. In one or more implementations, the first controller 220 is configured to control the memory, which in this example 200 includes the interface die 212 (e.g., a high bandwidth memory controller die) and the memory dies 210 (e.g., DRAM dies). Accordingly, the first controller 220 corresponds to the controller 108 in one or more implementations. Given this, in one or more implementations, the memory dies 210 correspond to the memory 110. Optionally, in at least one variation, the interface die 212 includes and/or implements the one or more controllers. Although not depicted in this example, in accordance with the described techniques, the memory dies 210 include one or more ECC engines, such as an ECC engine per die. In at least one variation, the second controller 222, which is optional, corresponds to a display controller. Alternatively or in addition, the second controller 222 is configured to control a different component, e.g., any input/output component. Although included in the illustrated example, in one or more implementations, the described techniques are implemented without the second controller 222, and instead only include the first controller 220, such as in a processor chip without an input/output controller.

The illustrated example 200 also includes a plurality of data links 224. In one or more implementations, the data links 224 are configured as 1024 data links, are used in connection with a high bandwidth memory stack, and/or having a speed of 500 megahertz (MHz). In one or more variations, such data links are configured differently. Here, the data links 224 are depicted linking the memory (e.g., the interface die 212 and the memory dies 210) to the processor chip(s) 208, e.g., to an interface with the second controller 222. In accordance with the described techniques, data links 224 are useable to link various components of the system.

In one or more implementations, one or more of the solder balls 214 and/or various other components (not shown), such as one or more of the solder balls 214 disposed between the printed circuit board 202 and the package substrate 204, are operable to implement various functions of the system, such as to implement Peripheral Component Interconnect Express (PCIe), to provide electrical current, and to serve as computing-component (e.g., display) connectors, to name just a few. In the context of another architecture, consider the following example.

FIG. 3 depicts a non-limiting example 300 of a stacked memory architecture. The illustrated example 300 includes one or more processor chip(s) 302, a controller 304, and a memory 306 having a plurality of stacked portions, e.g., dies (e.g., four dies in this example). Although the memory 306 is depicted with four dies in this example, in variations, the memory 306 includes more (e.g., 5, 6, 7, or 8+) or fewer (e.g., 3 or 2) dies without departing from the spirit or scope of the described techniques. In one or more implementations, the dies of the memory 306 are connected, such as through silicon vias, microbumps, hybrid bonds, or other types of connections. In this example 300, the dies of the memory 306 include a first tier 308 (e.g., To), a second tier 310 (e.g., T₁), a third tier 312 (e.g., T₂), and a fourth tier 314 (e.g., T₃). Given this, in one or more implementations, the memory 306 corresponds to the memory 110.

In this example 300, the processor chip(s) 302, the controller 304, and the dies of the memory 306 are arranged in a stacked arrangement, such that the controller 304 is disposed on the processor chip(s) 302, the first tier 308 of the memory 306 is disposed on the controller 304, the second tier 310 is disposed on the first tier 308, the third tier 312 is disposed on the second tier 310, and the fourth tier 314 is disposed on the third tier 312. In variations, components of a system for error correction for stacked memory are arranged differently, such as partially stacked and/or partially side by side.

In one or more implementations, the memory 306 corresponds to a DRAM and/or high bandwidth memory (HBM) cube stacked on a compute chip, such as the processor chip(s) 302. Examples of the processor chip(s) 302 include, but are not limited to, a CPU, GPU, FPGA, or other accelerator. In at least one variation, the system also includes the controller 304 (e.g., a memory interface die) disposed in the stack between the processor chip(s) 302 and the memory 306, i.e., stacked on top of the processor chip(s) 302. Alternatively or additionally, the controller 304 is on a same die as the processor chip(s) 302, e.g., in a side-by-side arrangement. This arrangement, when used with the described techniques, results in increased memory density and bandwidth, with minimal impact to power and performance to alleviate memory bottlenecks to system performance. Such arrangements can also be used in connection with the described error correction techniques with various other types of memories, such as FeRAM and MRAM.

In accordance with the described techniques, the memory 306 includes error correction code (ECC) engines 316. In the illustrated example 300, each tier of the memory 306 (e.g., each memory die) is depicted including an ECC engine 316. In variations, a tier of the memory includes more than one ECC engine 316. However, in at least one variation one or more tiers of the memory 306 do not include an ECC engine 316, such as when an ECC engine 316 of another (e.g., adjacent) memory tier is used to implement ECC for a tier without an engine.

The ECC engines 316 of the memory 306 are configured to communicate with one another. For example, the ECC engines 316 of different tiers of the memory 306 are configured to communicate with ECC engines 316 of one or more other tiers. In one or more implementations, for instance, the ECC engines 316 communicate (e.g., exchange with one another) a correlation map that relates a vulnerability of bits in a respective memory tier to bits in adjacent tiers or logic die (e.g., of the processor chip(s) 302). In terms of communicating data, the ECC engines 316 are configured for bidirectional communication, such that an individual ECC engine is configured to transmit data (e.g., a vulnerability correlation map) to another ECC engine and is also configured to receive data from the other ECC engine. In order to “coordinate” to perform ECC, when an ECC engine detects a detectable ECC event, the ECC engine that detected the event causes an indication associated with the event to be communicated (e.g., transmitted) to at least one other ECC engine. The at least one other ECC engine receives the indication. A given ECC engine is further configured to respond to ECC events communicated to it from one or more different ECC engines along with responding to the events the given ECC engine detects itself, thereby coordinating performance of ECC. In one or more variations, an ECC engine that detects an event causes an indication associated with the event to be communicated to all other ECC engines of the system and/or to a subset of the ECC engines of the system, e.g., the ECC engines within a “neighborhood” (number of hops) of the ECC engine that detected the event. In a scenario where an ECC event is detected by only one ECC engine, “coordinating” the ECC event involves the one ECC engine causing communication (e.g., transmission) of an indication associated with the event to at least a second ECC engine, e.g., all other ECC engines.

As used herein, “exchanging” a vulnerability correlation map refers to a first ECC engine communicating an updated and/or modified vulnerability correlation map to a second ECC engine when the first ECC engine detects an ECC event and the second ECC engine communicating an updated and/or modified vulnerability correlation map to the first ECC engine when the second ECC engine detects an ECC event. By exchanging vulnerability correlation maps in this way, the ECC engines each maintain a vulnerability correlation map that is updated to include vulnerabilities detected across the entirety of the system (or for a neighborhood) rather than a map that is updated to include only the events detected by the particular ECC engine.

The illustrated example 300 includes vertical exchange couplings 318, which connect the ECC engines 316 for exchanging correlation maps. In this way, the ECC engines 316 coordinate (e.g., by communicating with one another) to perform ECC through a correlation map both vertically and horizontally. In accordance with the described techniques, the ECC engines 316 are “dependent” because in one or more variations they depend on at least one other ECC engine 316 to generate a vertically and horizontally correlated map. The vertical exchange couplings 318 are configurable in various ways to enable the exchange of correlation maps between ECC engines 316 (e.g., of different tiers of the memory 306).

Although the ECC engines 316 are depicted included in the tiers of the memory 306 (e.g., one ECC engine 316 in each of the tiers), in at least one variation, ECC engines 316 that coordinate with one another to perform ECC are incorporated in a logic layer disposed between tiers of the memory 306. By doing so, ECC for correlated bits is performed in the background.

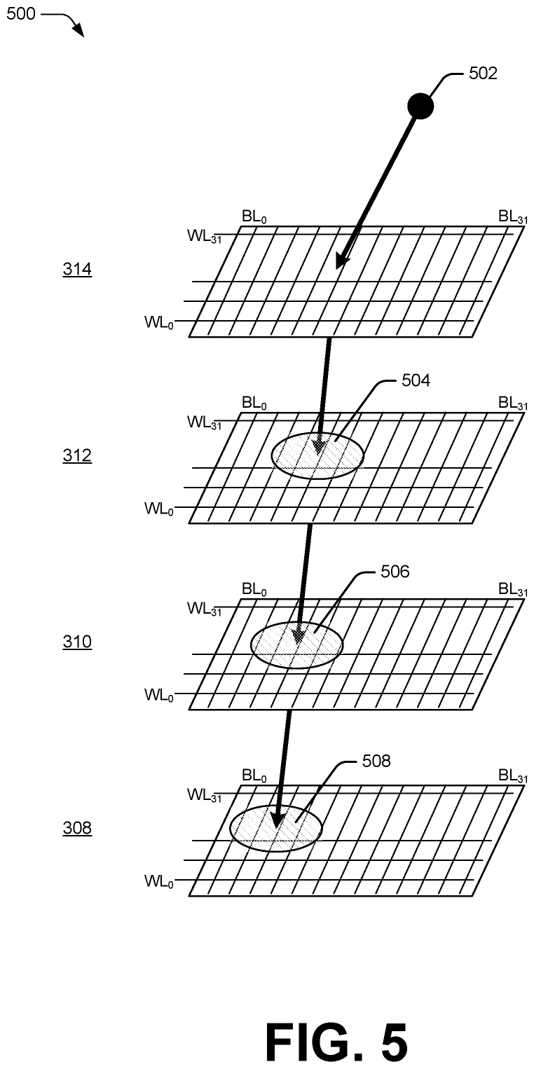

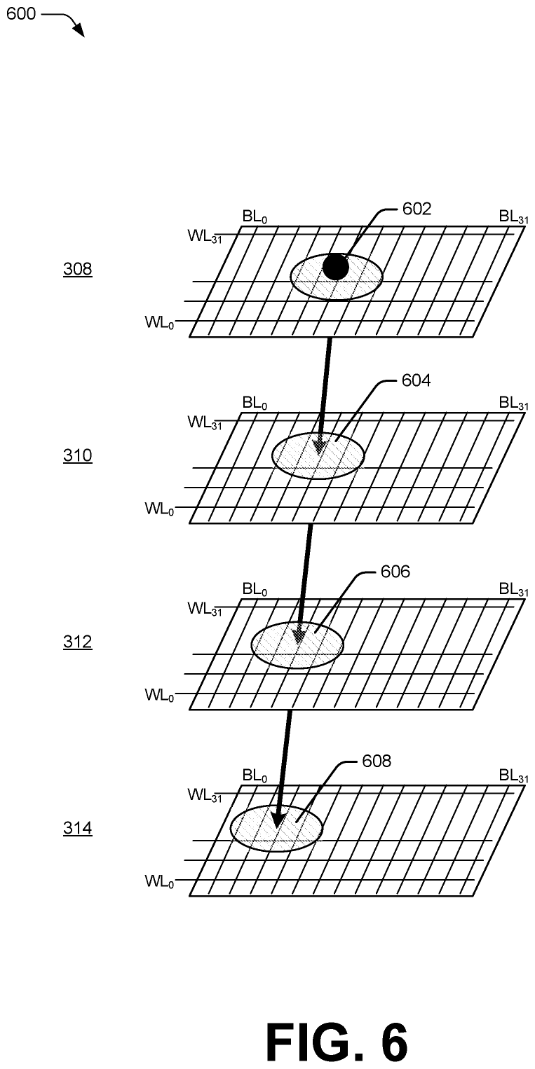

In the following discussion, consider an example in which there is a particle strike on a top tier of memory (e.g., FIG. 5) and/or an example in which a voltage or temperature variation occurs in the 3D integrated circuit (e.g., FIG. 6). Responsive to such an event, in one or more implementations, a correlation map is derived for the affected tier, e.g., by the ECC engine 316 of the tier 314 in the example 500 and by the ECC engine 316 of the tier 308 in the example 600. The ECC engines 316 perform coordinated ECC in accordance with one or more of the following approaches for stacked memory, thereby taking advantage of the 3D arrangement of stacked memory dies.

In one or more implementations, one or more of the ECC engines 316 performs targeted ECC in the background, e.g., outside of at least one cycle of read cycles. This reduces the performance impact from ECC and can be performed at different times from when actual data is being read from the memory 306. In a scenario where a first ECC is detected in a bottom (or lower) tier of the memory 306, such as due to a voltage droop, a second ECC is detected in a top (or higher) tier of the memory 306, such as due to a particle strike, and a correlation map indicates a potential multi-bit error in the bottom tier, at least one of the ECC engines 316 flags a probability of an uncorrectable error. In accordance with the described techniques, one or more portions of a memory die (e.g., the first tier 308, the second tier 310, the third tier 312, or the fourth tier 314) can be less susceptible to particle strikes, voltage droops, and/or temperature gradients. Such areas of the memory can have less or no ECC than other areas, which is effective as a tradeoff between ECC portions of the memory and non-ECC portions of the memory.

In one or more implementations, dies of the memory 306 are configured with monitors (not shown) to provide feedback about the memory. For instance, the monitors are configured to monitor various conditions (e.g., manufacturing variability, aging, thermal, memory retention, and/or other environmental conditions) of the memory or of portions of the memory (e.g., of one or more cells, rows, banks, die, etc.). These monitors provide feedback, such as feedback describing one or more of those conditions, to a logic die (e.g., a memory controller) or an ECC engine 316, which the logic die can use for memory allocation, frequency throttling of the memory (or portions of the memory), voltage throttling of the memory (or portions of the memory), and so forth. In one or more implementations, the ECC engine 316 uses this information to generate a correlation map, and thus coordinate ECC between multiple tiers of the memory 306.

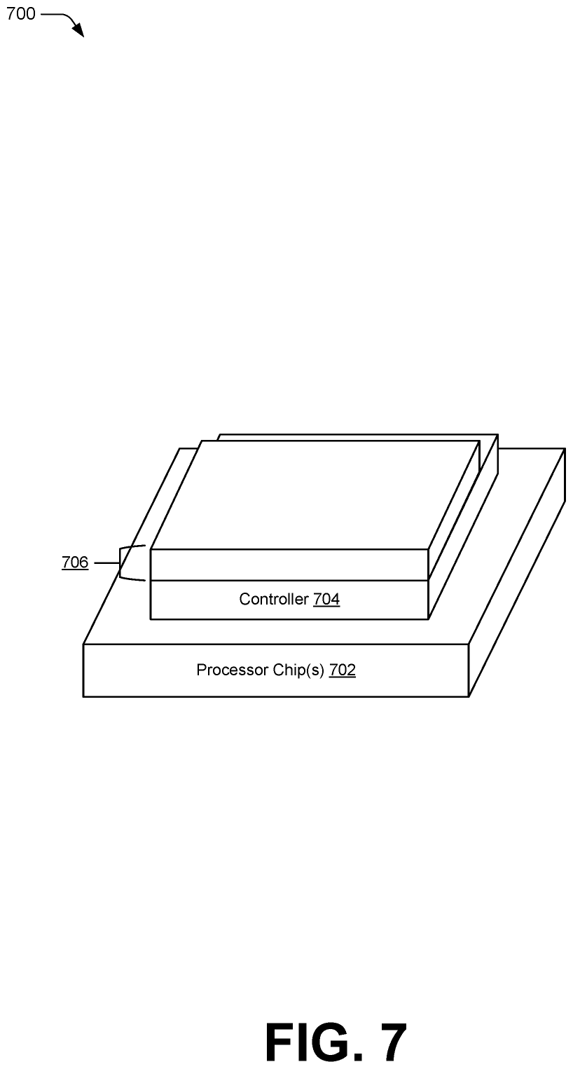

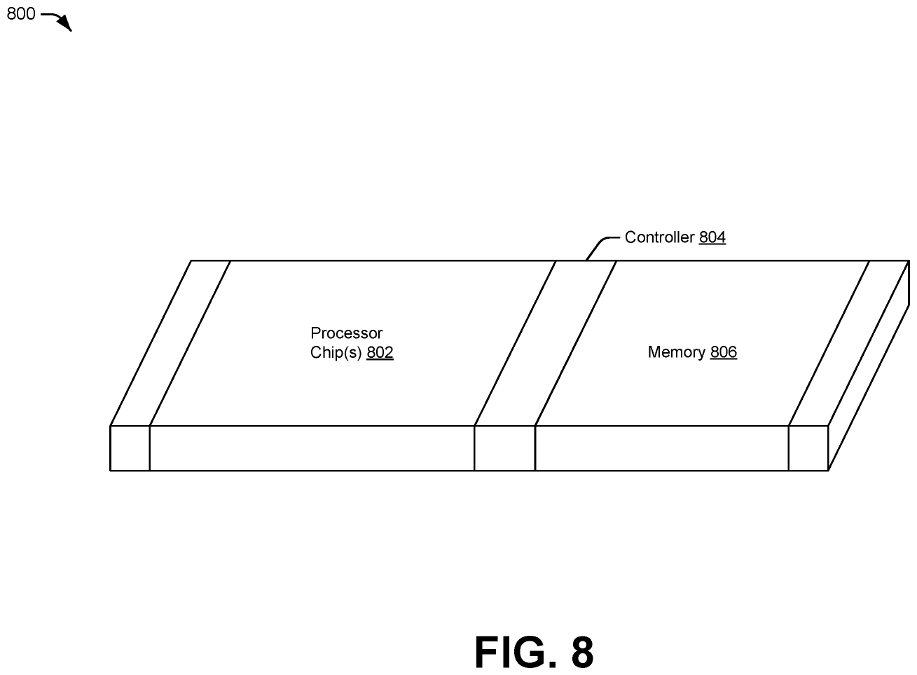

Although a stacked configuration having multiple memory dies is discussed just above, it is to be appreciated that in one or more implementations, the memory is configured differently, examples of which are discussed in relation to FIGS. 7 and 8.

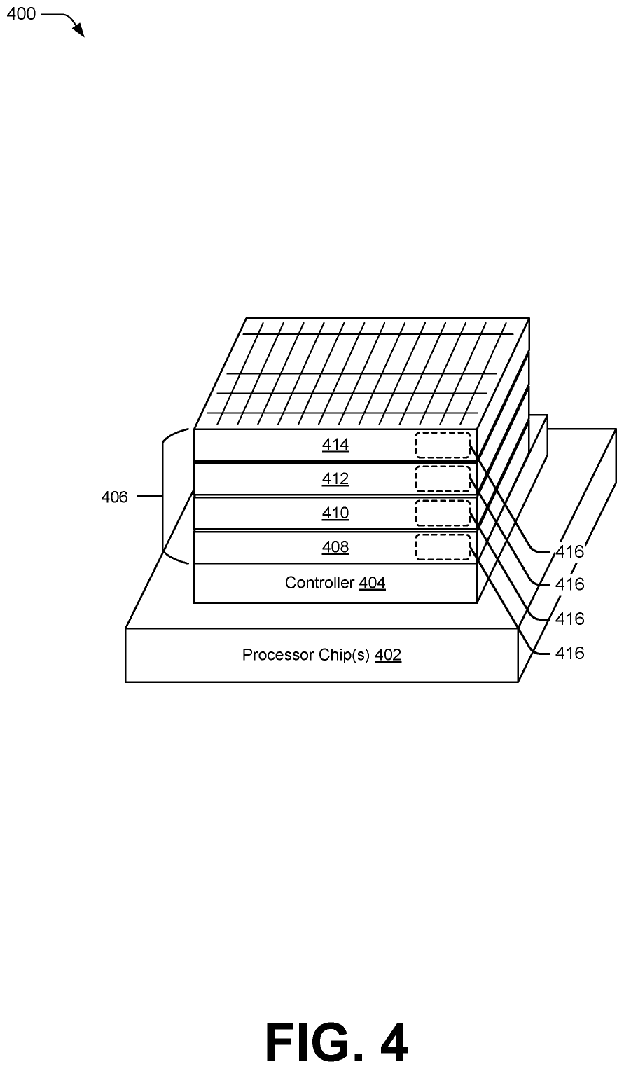

FIG. 4 depicts a non-limiting example 400 of error correction code memory without coordinated error correction.

The illustrated example 400 includes one or more processor chip(s) 402, a controller 404, and a memory 406 having a plurality of stacked portions, e.g., dies (e.g., four dies in this example). The illustrated example 400 also includes a plurality of dies of the memory 406, including a first tier 408 (e.g., To), a second tier 410 (e.g., T₁), a third tier 412 (e.g., T₂), and a fourth tier 414 (e.g., T₃). In addition, the tiers of the memory 406 are illustrated having ECC engines 416. In contrast to the example 300, though, the ECC engines 416 in the illustrated example 400 are not vertically connected (e.g., there are no vertical exchange couplings 318). This represents that the ECC engines 416 of the example 400 do not coordinate with one another to correlate ECC vertically, and instead implement ECC independently per die (e.g., conventional 2D ECC).

FIG. 5 depicts a non-limiting example 500 of coordinated error correction between tiers of memory.

The illustrated example 500 includes the first tier 308, the second tier 310, the third tier 312, and the fourth tier 314 of the memory 306. The illustrated example 500 also includes a detectable event 502, e.g., a particle strike on the tier 314 (the “top” tier) of the memory 306. In one or more implementations, the ECC engine 316 of the fourth tier 314 of the memory 306 detects the detectable event 502. The illustrated example 500 also depicts first correlated bits 504 flagged for ECC (e.g., in a correlation map), the first correlated bits 504 include one or more bits of the third tier 312 that are potentially affected by the detectable event to the fourth tier 314, e.g., based on a trajectory of the particle strike. The illustrated example 500 also depicts second correlated bits 506 flagged for ECC (e.g., in the correlation map), the second correlated bits 506 include one or more bits of the second tier 310 that are potentially affected by the detectable event to the fourth tier 314, e.g., based on a trajectory of the particle strike. The illustrated example 500 also depicts third correlated bits 508 flagged for ECC (e.g., in the correlation map), the third correlated bits 508 include one or more bits of the first tier 308 that are potentially affected by the detectable event to the fourth tier 314, e.g., based on a trajectory of the particle strike. Accordingly, the illustrated example 500 depicts a possible correlation in bitflips for 3D IC, e.g., due to a particle strike. In one or more implementations, at least two of a plurality of ECC engines, associated with the different tiers of the memory, coordinate (e.g., communicate) with one another to perform ECC for the different tiers, such as by communicating information about the detectable event 502 (e.g., the bits affected) on the tier 314 from a first ECC engine to a second ECC engine and thus cause the correlated bits of at least one other tier to be flagged for ECC (e.g., by the second ECC engine).

FIG. 6 depicts another non-limiting example 600 of coordinated error correction between tiers of memory.

The illustrated example 500 includes the first tier 308, the second tier 310, the third tier 312, and the fourth tier 314 of the memory 306. However, the tiers of the memory 306 are depicted in inverse order from the examples 500 and 300. Despite being illustrated in this way, in one or more implementations, the first tier 308 is physically closer to the processor chip(s) 302 than the fourth tier 314.

The illustrated example 600 also includes a detectable event 602, e.g., a voltage or temperature variation on the tier 308 (the “bottom” tier) of the memory 306. In one or more implementations, the ECC engine 316 of the first tier 308 of the memory 306 detects the detectable event 602. In one or more implementations, the memory 306 is configured with one or more monitors (e.g., thermal sensor or retention monitor) embedded therein to detect conditions of the memory (e.g., of different portions of the memory).

The illustrated example 600 also depicts first correlated bits 604 flagged for ECC (e.g., in a correlation map), the first correlated bits 604 include one or more bits of the second tier 310 that are potentially affected by the detectable event to the first tier 308, e.g., based on a detected location of the voltage or temperature variation. The illustrated example 600 also depicts second correlated bits 606 flagged for ECC (e.g., in the correlation map), the second correlated bits 606 include one or more bits of the third tier 312 that are potentially affected by the detectable event to the first tier 308, e.g., based on a detected location of the voltage or temperature variation. The illustrated example 600 also depicts third correlated bits 608 flagged for ECC (e.g., in the correlation map), the third correlated bits 608 include one or more bits of the fourth tier 314 that are potentially affected by the detectable event to the first tier 308, e.g., based on a detected location of the voltage or temperature variation. Accordingly, the illustrated example 600 depicts a possible correlation in bitflips for 3C IC, e.g., due to a detected voltage or temperature variation.

In one or more implementations, at least two of a plurality of ECC engines, associated with the different tiers of the memory, coordinate (e.g., communicate) with one another to perform ECC for the different tiers, such as by communicating information about the detectable event 602 (e.g., the bits affected) on the tier 308 from a first ECC engine to a second ECC engine and thus cause the correlated bits of at least one other tier to be flagged for ECC (e.g., by the second ECC engine).

FIG. 7 depicts a non-limiting example 700 of another stacked memory architecture. The illustrated example 700 includes one or more processor chip(s) 702, a controller 704, and a memory 706. In at least one variation, the memory 706 is non-volatile memory, such as Ferro-electric RAM or Magneto resistive RAM. Alternatively, the memory 706 is a volatile memory, example of which are mentioned above. In variations, the components (e.g., the one or more processor chip(s) 702, the controller 704, and the memory 706) are connected in any of a variety of ways, such as those discussed above. Given this, in one or more implementations, the memory 706 corresponds to the memory 110.

In this example 700, the processor chip(s) 702, the controller 704, and the memory 706 are arranged in a stacked arrangement, such that the controller 704 is disposed on the processor chip(s) 702, and the memory 706 is disposed on the controller 704. As noted above, components of a system for error correction for stacked memory are arranged differently in variations without departing from the spirit of the described techniques. In one or more implementations where the memory 706 is a non-volatile memory, the memory 706 has a higher temperature tolerance than one or more volatile-memory implementations. As another example arrangement of components, consider the following example of FIG. 8.

FIG. 8 depicts a non-limiting example 800 of a non-stacked memory architecture having a memory and processor on a single die. The illustrated example 800 includes one or more processor chip(s) 802, a controller 804, and a memory 806. In at least one variation, the memory 806 is non-volatile memory, such as a logic compatible Ferro-electric RAM or Magneto resistive RAM. Alternatively, the memory 806 is a volatile memory, examples of which are mentioned above. In variations, the components (e.g., the one or more processor chip(s) 802, the controller 804, and the memory 806) are connected in any of a variety of ways, such as those discussed above.

In at least one example, such as the illustrated example 800, the one or more processor chip(s) 802, the controller 804, and the memory 806 are disposed side-by-side on a single die, e.g., each of those components is disposed on a same die. For instance, the controller 804 is connected in a side-by-side arrangement with the processor chip(s) 802, and the memory 806 is connected in a side-by-side arrangement with the controller 804, such that the controller 804 is disposed between the memory 806 and the processor chip(s) 802. In variations, the components of a system for error correction for stacked memory are arranged in different side-by-side arrangements (or partial side-by-side arrangements) without departing from the spirit or scope of the described techniques.

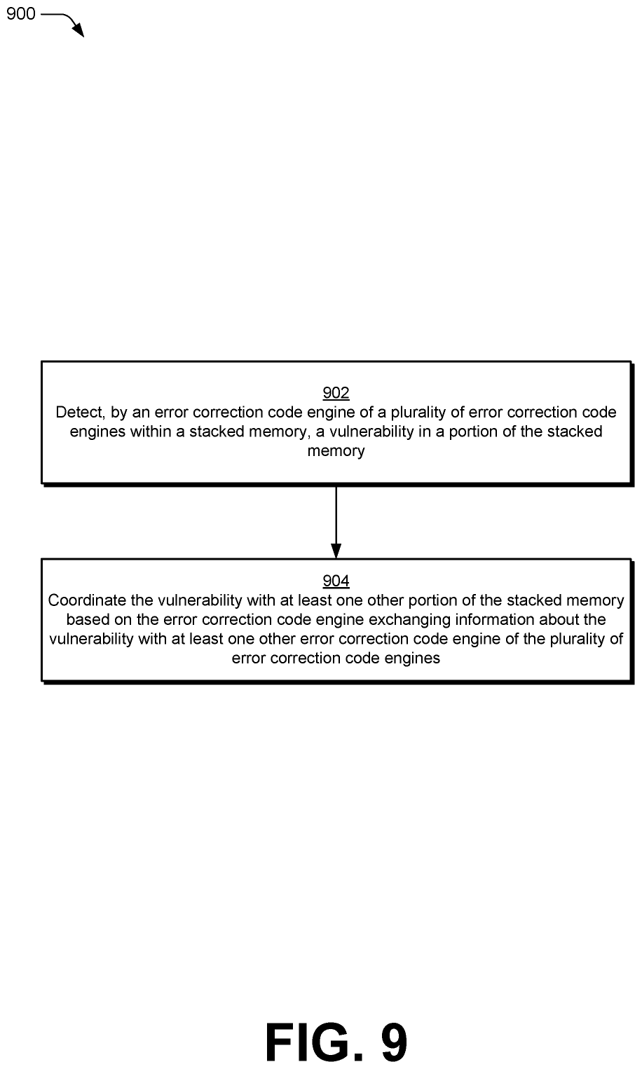

FIG. 9 depicts a procedure in an example 900 implementation of error correction for stacked memory.

A vulnerability in a portion of a stacked memory is detected by an error correction code engine of a plurality of error code engines within the stacked memory (block 902). The vulnerability is coordinated with at least one other portion of the stacked memory based on the error correction code engine exchanging information about the vulnerability with at least one other error correction code engine of the plurality of error correction code engines (block 904).

It should be understood that many variations are possible based on the disclosure herein. Although features and elements are described above in particular combinations, each feature or element is usable alone without the other features and elements or in various combinations with or without other features and elements.

The various functional units illustrated in the figures and/or described herein (including, where appropriate, the memory 110, the ECC engine 112, the controller 108, and the core 106) are implemented in any of a variety of different manners such as hardware circuitry, software or firmware executing on a programmable processor, or any combination of two or more of hardware, software, and firmware. The methods provided are implemented in any of a variety of devices, such as a general purpose computer, a processor, or a processor core. Suitable processors include, by way of example, a general purpose processor, a special purpose processor, a conventional processor, a digital signal processor (DSP), a graphics processing unit (GPU), a parallel accelerated processor, a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), and/or a state machine.

In one or more implementations, the methods and procedures provided herein are implemented in a computer program, software, or firmware incorporated in a non-transitory computer-readable storage medium for execution by a general purpose computer or a processor. Examples of non-transitory computer-readable storage mediums include a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A system comprising:
a stacked memory; and
a plurality of error correction code engines to detect vulnerabilities in the stacked memory and coordinate at least one vulnerability detected for a portion of the stacked memory to at least one other portion of the stacked memory.

2. The system of claim 1, wherein the portion of the stacked memory and the at least one other portion of the stacked memory correspond to different memory dies.

3. The system of claim 1, wherein the stacked memory is a DRAM memory.

4. The system of claim 1, wherein coordination of the at least one vulnerability includes exchanging a vulnerability correlation map between at least two error correction code engines.

5. The system of claim 1, wherein error correction code engines disposed on different tiers of the stacked memory are communicably coupled.

6. The system of claim 5, wherein the coordination of the at least one vulnerability includes a first error correction code engine communicating with a second error correction code engine.

7. The system of claim 1, wherein at least one engine of the plurality of error correction code engines is disposed between tiers of the stacked memory.

8. A method comprising:
detecting, by an error correction code engine of a plurality of error correction code engines within a stacked memory, a vulnerability in a portion of the stacked memory; and
coordinating the vulnerability with at least one other portion of the stacked memory based on the error correction code engine exchanging information about the vulnerability with at least one other error correction code engine of the plurality of error correction code engines.

9. The method of claim 8, wherein the error correction code engine is communicatively coupled to the at least one other error correction code engine.

10. The method of claim 9, wherein the coordinating further comprises communicating, by the error correction code engine, the information about the vulnerability to the at least one other error correction code engine.

11. The method of claim 10, wherein the information comprises a vulnerability correlation map.

12. The method of claim 8, wherein the portion of the stacked memory and the at least one other portion of the stacked memory correspond to different memory dies.

13. The method of claim 8, wherein the stacked memory is a DRAM memory.

14. The method of claim 8, wherein coordination of the at least one vulnerability includes exchanging a vulnerability correlation map between at least two error correction code engines.

15. A system comprising:
a stacked memory comprising a plurality of dies;
a first error correction code engine associated with a first die of the plurality of dies; and
a second error correction code engine associated with a second die of the plurality of dies, wherein the first error correction code engine and the second error correction code engine are configured to coordinate at least one vulnerability detected for at least one of the first die or the second die of the plurality of dies.

16. The system of claim 15, wherein the first error correction code engine is configured to detect a vulnerability associated with the first die of the plurality of dies.

17. The system of claim 16, wherein the first error correction code engine is further configured to communicate information about the vulnerability to the second error correction code engine.

18. The system of claim 15, wherein the second error correction code engine is configured to detect a vulnerability associated with the second die of the plurality of dies and communicate information about the vulnerability to the first error correction code engine.

19. The system of claim 15, wherein the stacked memory is a DRAM memory.

20. The system of claim 15, wherein the first error correction code engine and the second error correction code engine are configured to coordinate at least one vulnerability by exchanging a vulnerability correlation map.
